(19) United States
(12) Patent Application Publication
(10) Pub. No.: US 2025/0294709 A1
(43) Pub. Date: Sep. 18, 2025

(54) MECHANICAL PUMP-FREE FLOW BOILING HEAT SINK

(71) Applicant: XI'AN JIAOTONG UNIVERSITY, Xi'an (CN)

(72) Inventors: Xiaoping YANG, Xi'an (CN); Qingjie CUI, Xi'an (CN); Li SHEN, Xi'an (CN); Yonghai ZHANG, Xi'an (CN); Ziyi YOU, Xi'an (CN); Jinjia WEI, Xi'an (CN)

(21) Appl. No.: 19/222,951

(22) Filed: May 29, 2025

(30) Foreign Application Priority Data
Jan. 20, 2025 (CN) 202510084388.6

(51) Int. Cl. H05K 7/20

(52) U.S. Cl. CPC H05K 7/2039; H05K 7/20309; H05K 7/20318; H05K 7/20327; H05K 7/20336

(57) ABSTRACT

A mechanical pump-free flow boiling heat sink, including an evaporator, a two-phase flow steam injector, a first condenser, a boiling pool and a second condenser. A vapor outlet of the evaporator is communicated with a vapor-phase inlet of the two-phase flow steam injector. A liquid-phase outlet of the evaporator is communicated with an inlet of the boiling pool. An outlet of the boiling pool is communicated with an inlet of the second condenser. An outlet of the second condenser is communicated with a liquid-phase inlet of the two-phase flow steam injector. An outlet of the two-phase flow steam injector is communicated with an inlet of the first condenser. An outlet of the first condenser is communicated with an inlet of the evaporator.

### CROSS-REFERENCE TO RELATED APPLICATIONS

This application claims the benefit of priority from Chinese Patent Application No. 202510084388.6, filed on Jan. 20, 2025. The content of the aforementioned application, including any intervening amendments made thereto, is incorporated herein by reference in its entirety.

### TECHNICAL FIELD

This application relates to heat dissipation of electronic devices, and more particularly to a mechanical pump-free flow boiling heat sink.

### BACKGROUND

The rapid development of science and technology has led to the continuous improvement of the integration and performance of electronic devices, making the dissipation of a heat flux up to 100 W/cm² increasingly prominent. This seriously threatens the performance, safety and reliability of electronic devices. Although the mechanical pump-driven flow boiling heat dissipation loop can offer an effective dissipation at a higher heat flux, the internal moving parts rotating under a high speed and liquid storage devices significantly reduce the system reliability and increase the system weight and volume, limiting its application in some specific scenarios.

The mechanical pump-driven cooling system requires an external power source to maintain the fluid circulation. In addition, the internal moving parts suffer high risks of wear and failure, affecting its operation stability. The operation reliability is crucial in some demanding application scenarios, such as space exploration or military facility. Therefore, it is particularly important to seek a heat-dissipation solution without external power source and internal moving parts.

Some of the existing mechanical pump-free flow boiling heat dissipation loops have the following defects. Firstly, the operation is dependent on the gravity, which limits its applicability in some specific application occasions. Secondly, when the heat load increases, the liquid supply of the boiling pool may be delayed, resulting in the occurrence of dry burning.

Chinese Patent Publication No. 109855456A disclosed a loop heat pipe heat sink with a two-phase flow steam injector, in which a boiling pool is located at the outlet of the two-phase flow steam injector, and its working fluid is a non-equilibrium two-phase flow formed by ejection mixing of a high-temperature vapor phase and a liquid phase from the compensation chamber.

Moreover, the operation of the boiling pool is accompanied by the generation of a large amount of gas is generated during, which will result in a local pressure rise, thereby hindering the vapor flow at the evaporator outlet. This may weaken the ability of the two-phase flow steam injector to extract liquid from the compensation chamber. The obstruction of the coolant extraction may cause a temperature increase in the hot liquid received by the boiling pool, thereby exacerbating the pressure rise in the boiling pool. Such a positive feedback mechanism will deteriorate the operating state of the device, and may cause complete stagnation of the two-phase flow steam injector in some extreme conditions. The evaporator lacks an independent liquid outlet, and only relies on the returned working fluid at the condenser outlet for cooling, resulting in a high working fluid temperature in the evaporator compensation chamber. Only a part of the working fluid passes through the two-phase flow steam injector, and the remaining fluid flows back to the compensation chamber, indicating the presence of a flow distribution issue.

### SUMMARY

An object of the disclosure is to provide a mechanical pump-free flow boiling heat sink, in which based on the ejection and pressurization abilities of a two-phase flow steam injector, the supercooled liquid (with a mass flow rate dozens to hundreds of times the mass flow rate of vapor at the evaporator outlet) is efficiently pumped into a boiling pool to form a flow boiling within the core heat dissipation area, so as to achieve effective heat dissipation of electronic devices with a high heat flux.

In order to achieve the above object, the following technical solutions are adopted.

This application provides a mechanical pump-free flow boiling heat sink, comprising:
at least one evaporator;
a two-phase flow steam injector;
a first condenser;
at least one boiling pool; and
a second condenser;
wherein a vapor outlet of each of the at least one evaporator is communicated with a vapor-phase inlet of the two-phase flow steam injector;
a liquid-phase outlet of each of the at least one evaporator is communicated with an inlet of a corresponding one of the at least one boiling pool; and
an outlet of each of the at least one boiling pool is communicated with an inlet of the second condenser, and an outlet of the second condenser is communicated with a liquid-phase inlet of the two-phase flow steam injector; and an outlet of the two-phase flow steam injector is communicated with an inlet of the first condenser, and an outlet of the first condenser is communicated with an inlet of each of the at least one evaporator.

In some embodiments, the two-phase flow steam injector comprises a vapor nozzle, a liquid nozzle and a mixing section; the vapor nozzle and the liquid nozzle are both communicated with the mixing section; the liquid nozzle is located at a periphery of the vapor nozzle; the vapor nozzle is communicated with the vapor outlet of each of the at least one evaporator; and the liquid nozzle is communicated with the outlet of the second condenser.

In some embodiments, the vapor nozzle and the mixing section are each a Laval nozzle.

In some embodiments, the mixing section comprises a mixing chamber, a throat and a diffusion zone communicated in sequence; the diffusion zone is communicated with the inlet of the first condenser; the vapor nozzle has an inlet end with an inner diameter of 1-2 mm and a throat with an inner diameter of 0.6-1.2 mm; and an inner diameter of the throat of the mixing section is 1-1.2 mm.

In some embodiments, the liquid nozzle is connected to the second condenser through a liquid pipeline; and the liquid pipeline is inserted into the two-phase flow steam injector at a circumferential angle of 30°-60° and an axial angle of 30°-60°.

In some embodiments, each of the at least one evaporator comprises a base plate and a compensation chamber arranged on the base plate; a capillary wick is provided below the compensation chamber; a vapor channel is provided below the capillary wick; a vapor collecting groove is provided at a side of the vapor channel, and is communicated with the vapor channel; and the vapor collecting groove is connected to the vapor nozzle through a vapor pipeline.

In some embodiments, the capillary wick comprises an upper layer and a lower layer; the lower layer is formed by sintering a brass powder with a particle size of 800-1200 mesh; and the upper layer is formed by sintering a nickel powder with a particle size of 300-500 mesh.

In some embodiments, the capillary wick and the base plate are molded by integrated sintering.

In some embodiments, a bottom surface of the each of the at least one boiling pool is provided with a plurality of square column microstructures; a gap is provided between any adjacent two of the plurality of square column microstructures; a surface of each of the plurality of square column microstructures is distributed with micron-sized particles by sintering; and a microporous structure is formed between the micron-sized particles.

In some embodiments, a plurality of evaporators and a plurality of boiling pools are provided; and the plurality of evaporators are connected in series, and the plurality of boiling pools are connected in series; or the plurality of evaporators are connected in parallel, and the plurality of boiling pools are connected in parallel.

Compared to the prior art, the present disclosure has the following beneficial effects.

1. In the present disclosure, a two-phase flow steam injector is introduced at the combined outlet of the at least one evaporator and the at least one boiling pool. This makes the heat sink free of external power sources and moving parts, thereby significantly increasing the device reliability. Moreover, only a small amount of heat is required to be applied to the at least one evaporator to generate vapor, and then the vapor enters the two-phase flow steam injector to inject dozens of times the supercooled liquid from the compensation chamber into the boiling pool cavity to form a flow boiling heat exchange effect. This successfully addresses the issue of insufficient liquid supply in the boiling pool, thereby achieving excellent flow boiling heat transfer performance with a high critical heat flux density, resulting in efficient heat dissipation for high heat flux density electronic devices.

2. The working fluid of the at least one boiling pool is sourced solely from the liquid phase of the compensation chamber, which has a lower temperature than that of a loop heat pipe heat sink. Therefore, in view of the configuration of the loop heat pipe heat sink, the steady-state temperature of the bottom surface of the boiling pool can reach over 120° C., significantly exceeding the glass transition threshold of typical electronic device packaging materials. This leads to a surge in the risk of thermomechanical failure, making it difficult to meet heat dissipation requirements of high-density integrated circuits.

3. In the present disclosure, the at least one boiling pool is arranged at the liquid outlet of the at least one evaporator, and the outlet of the at least one boiling pool is communicated with the liquid inlet of the two-phase flow steam injector, where the pressure is relatively low. The high pressure generated in the at least one boiling pool facilitates the ejection process of the two-phase flow steam injector, promoting thorough mixing of the supercooled liquid with the high-temperature vapor. This is more conducive to system circulation and reducing the working medium temperature before entering the first condenser, thereby reducing the workload of the first condenser.

4. The present disclosure achieves a higher boost ratio and injection ratio by optimizing parameters of internal components of the two-phase flow steam injector, resulting in improved performance of the heat sink.

5. In the present disclosure, the two-phase flow steam injector is adopted, and the inlet of the injected liquid is arranged in the compensation chamber located at the back of the at least one evaporator. The liquid heated by “heat leakage” in the compensation chamber is removed by the vapor injection effect, and replaced by the fresh cold liquid sent back, forming a hot and cold fluid exchange, which can avoid the instability caused by the “heat leakage”.

6. The present disclosure does not involve diversion, and has a sufficient amount of ejected liquid, which avoids the ineffective condensation of vapor generated by the at least one evaporator due to insufficient ejected liquid, and the adverse effect on the performance of the at least one boiling pool due to the gas-liquid working fluid at the inlet of the at least one boiling pool.

7. The two-phase flow steam injector of the present disclosure is composed of a zoom-type vapor nozzle and a mixing section with a variable cross-section connected in series. The vapor is expanded and accelerated in the nozzle to form a local negative pressure. The supercooled liquid is injected into the mixing chamber and directly contacts the vapor for condensation to form a supersonic gas-liquid flow. A condensation shock wave is generated near the throat to achieve a sudden pressure rise, and then the pressure is continuously increased in the diffusion zone to form a high-pressure liquid, thereby completing the conversion of the vapor internal energy into the liquid pressure energy.

8. Each of the at least one boiling pool of the present disclosure is provided with a plurality of square column microstructures gaps between any adjacent square column microstructures. A surface of each of the plurality of square column microstructures is sintered with micron-sized particles, and a microporous structure is formed between the micron-sized particles, which have the distribution characteristics of nanoclusters. The presence of nanoclusters forms numerous vaporization cores, thereby significantly enhancing the convective boiling heat transfer coefficient. Meanwhile, the micropores between the particles effectively enhance the capillary rehydration capacity of the wall surface, and the gaps between adjacent micro-columns provide channels for the flow of the micro-liquid layer near the wall, significantly increasing the critical heat flux density. In addition, due to the dense distribution of vaporization cores in the nanoclusters, frequent bubble coalescence occurs during bubble growth, and the excess surface energy is converted into kinetic energy of the coalesced large bubbles detaching from the wall, resulting in a bubble bouncing detachment effect that effectively overcomes the problem of insufficient driving force for bubble detachment.

### BRIEF DESCRIPTION OF THE DRAWINGS

In order to more clearly illustrate the technical solutions in the embodiments of the present disclosure or in the prior art, the drawings needed in the description of embodiments will be briefly introduced below. Obviously, presented in the drawings are only some embodiments of the present disclosure, which are not intended to limit the disclosure. For those of ordinary skill in the art, other drawings can be obtained based on these drawings without exerting creative efforts.

FIG. 1 schematically shows a mechanical pump-free flow boiling heat sink in accordance with an embodiment of the present disclosure in an operating state;

FIG. 2 is a structural diagram of the mechanical pump-free flow boiling heat sink in accordance with an embodiment of the present disclosure;

FIG. 3 is a sectional view of an evaporator of the mechanical pump-free flow boiling heat sink in FIG. 2 along A-A line;

FIG. 4 is a structural diagram of a plurality of evaporators connected in parallel in accordance with an embodiment of the present disclosure;

FIG. 5 is a structural diagram of a capillary wick of the mechanical pump-free flow boiling heat sink in accordance with an embodiment of the present disclosure;

FIG. 6 is a structural diagram of a two-phase flow steam injector of the mechanical pump-free flow boiling heat sink in accordance with an embodiment of the present disclosure;

FIG. 7 schematically shows circumferential tilt of the two-phase flow steam injector in accordance with an embodiment of the present disclosure;

FIG. 8 schematically shows axial tilt of the two-phase flow steam injector in accordance with an embodiment of the present disclosure;

FIG. 9 is a structural diagram of a boiling pool of the mechanical pump-free flow boiling heat sink in accordance with an embodiment of the present disclosure;

FIG. 10 is a structural diagram of a plurality of boiling pools connected in parallel in accordance with an embodiment of the present disclosure; and

FIG. 11 is a structural diagram of a plurality of boiling pools connected in series in accordance with an embodiment of the present disclosure.

### DETAILED DESCRIPTION OF EMBODIMENTS

This application will be clearly and completely described below with reference to the accompanying drawings and embodiments. Obviously, described below are merely some embodiments of the disclosure, instead of all embodiments of the disclosure. Based on the embodiments of the disclosure, all other embodiments obtained by those of ordinary skill in the art without making creative efforts shall fall within the scope of the disclosure defined by the appended claims.

In the description of the present disclosure, it should be understood that orientation or position relationships indicated by terms such as “center”, “up”, “down”, “front”, “back”, “left”, “right”, “vertical”, “horizontal”, “top”, “bottom”, “inside” and “outside” are based on the orientation or position relationships shown in the drawings, which are merely for the convenience of describing the present application and simplifying the description, but not intended to indicate or imply that the device or element referred to must have a particular orientation, or be constructed or operated in a particular orientation. Therefore, these terms cannot be construed as a limitation of the present application.

In the description of this application, unless otherwise clearly specified and limited, terms such as “installation”, “connection”, and “fixing” should be understood in a broad sense. For example, “connect” can indicate a fixed connection, a detachable connection, or an integrated state. For those of ordinary skill in the art, the specific meanings of the above terms in the present disclosure can be understood according to specific circumstances.

In addition, relational terms such as “first” and “second” are only descriptive, and cannot be understood as indicating or implying relative importance or implicitly indicating the number of indicated technical features. Therefore, features defined as “first” and “second” can explicitly or implicitly include at least one of the features. In the description of this application, “a plurality of” means at least two, unless otherwise expressly and specifically limited.

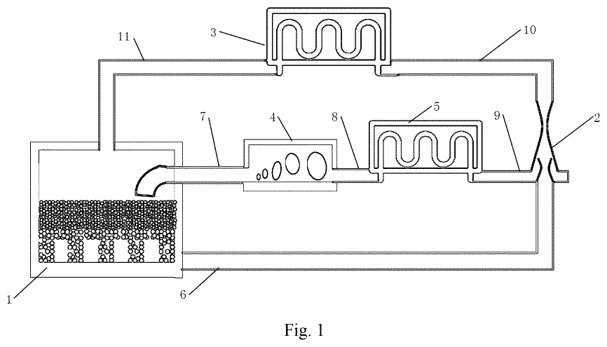

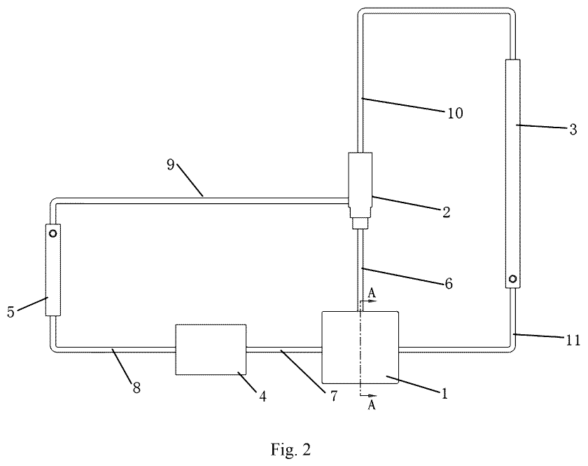

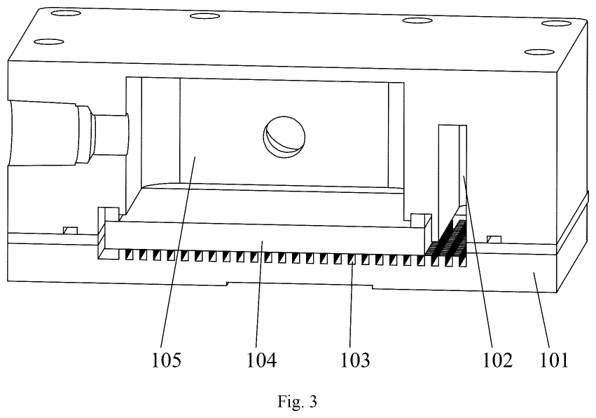

Referring to FIGS. 1-11, a mechanical pump-free flow boiling heat sink is provided, which includes at least one evaporator 1, a two-phase flow steam injector 2, a first condenser 3, at least one boiling pool 4 and a second condenser 5.

A vapor outlet of each of the at least one evaporator 1 is communicated with a vapor-phase inlet of the two-phase flow steam injector 2 through a first vapor pipeline 6. In a first case where two or more evaporators 1 and two or more boiling pools 4 are provided, liquid-phase outlets of the evaporators 1 are respectively communicated with inlets of the boiling pools 4 through a first liquid pipeline 7. In a second case where two or more evaporators 1 are provided, and one boiling pool 4 is provided, liquid-phase outlets of the evaporators 1 are all communicated with an inlet of the boiling pool 4 through the first liquid pipeline 7. In a third case where the number of the at least one evaporator 1 is one, and two or more boiling pools 4 are provided, inlets of the boiling pools 4 are all communicated with a liquid-phase outlet of the evaporator 1 through the first liquid pipeline 7. An outlet of each of the at least one boiling pool 4 is communicated with an inlet of the second condenser 5 through a second vapor pipeline 8. An outlet of the second condenser 5 is communicated with a liquid-phase inlet of the two-phase flow steam injector 2 through a second liquid pipeline 9. An outlet of the two-phase flow steam injector 2 is communicated with an inlet of the first condenser 3 through a third liquid pipeline 10. An outlet of the first condenser 3 is communicated with an inlet of each of the at least one evaporator 1 through a fourth liquid pipeline 11.

Referring to FIGS. 1-3, the at least one evaporator 1 adopts a square column structure or cylindrical structure. In order to ensure air tightness, each of the at least one evaporator 1 is formed by diffusion welding as a whole. The at least one evaporator 1 each includes a base plate 101, a vapor collecting groove 102, a vapor channel 103, a capillary wick 104 and a compensation chamber 105. The capillary wick 104 is arranged at a central vacancy of the base plate 101. The compensation chamber 105 is arranged above the capillary wick 104, and is connected to both the base plate 101 and a side wall of a corresponding one of the at least one evaporator 1. The capillary wick 104 can provide capillary driving force. The vapor channel 103 is arranged below the capillary wick 104. The vapor collecting groove 102 is arranged at a side of the vapor channel 103 close to the first vapor pipeline 6, and is communicated with the vapor channel 103. The vapor collecting groove 102 is communicated with the vapor-phase inlet of the two-phase flow steam injector 2 through the first vapor pipeline 6. The vapor collecting groove 102 and the vapor channel 103 are precisely mounted on the base plate 101 by a mechanical processing method.

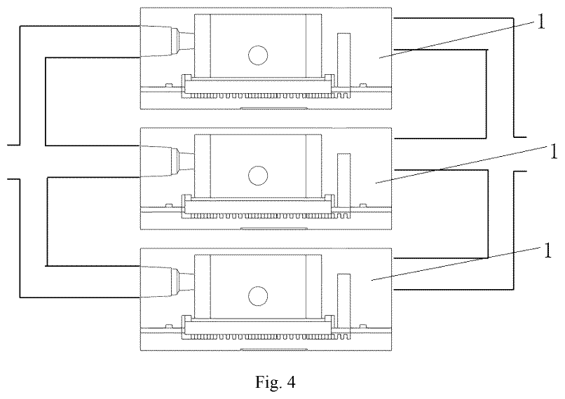

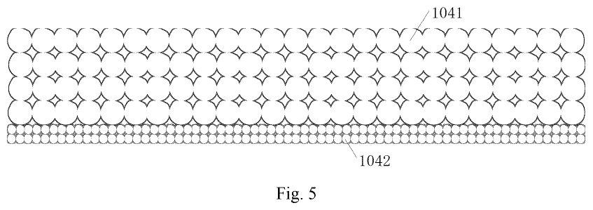

Due to the low surface tension of the low-boiling-point working fluid (with a boiling point below 30° C.), it is difficult to form a stable pressure difference, so the capillary wick inside the evaporator needs to have low heat leakage and large capillary force. Therefore, referring to FIG. 5, in this embodiment, the capillary wick 104 adopts a layered arrangement during preparation. Specifically, the capillary wick 104 includes an upper layer 1041 and a lower layer 1042. The lower layer 1042 is formed by sintering a high-mesh brass powder with a particle size of 800-1200 mesh. The upper layer 1041 is formed by sintering a low-mesh nickel powder with a particle size of 300-500 mesh to reduce heat leakage and flow resistance inside the capillary wick. In addition, the capillary wick 104 is combined with the base plate 101 by means of integrated sintering. It should be noted that, in order to adapt to the conditions of multiple chip heat sources, referring to FIG. 4, in this embodiment, the at least one evaporator 1 can also be configured as a plurality of evaporators that are connected in parallel.

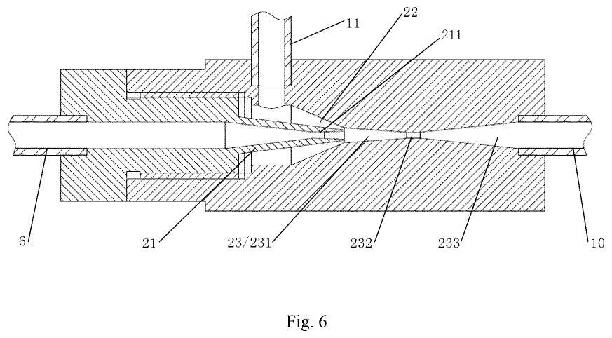

Referring to FIGS. 6-8, the two-phase flow steam injector 2 includes a vapor nozzle 21, a liquid nozzle 22 and a mixing section 23. The vapor nozzle 21 and the liquid nozzle 22 are both communicated with the mixing section 23. The liquid nozzle 22 is located at a periphery of the vapor nozzle 21, that is, the liquid nozzle 22 is an annular gap formed by an outlet of the vapor nozzle 21 and an inlet of the mixing section 23.

The vapor nozzle 21 and the mixing section 23 are each a Laval nozzle. The mixing section 23 includes a mixing chamber 231, a throat 232 and a diffusion zone 233 communicated in sequence. The mixing chamber 231 is communicated with the outlet of the vapor nozzle 21 and an outlet of the liquid nozzle 22. The diffusion zone 233 is communicated with the inlet of the first condenser 3 through the third liquid pipeline 10. An inlet of the vapor nozzle 21 is communicated with the vapor outlet of each of the at least one evaporator 1 through the first vapor pipeline 6. An inlet of the liquid nozzle 22 is communicated with the outlet of the second condenser 5 through the fourth liquid pipeline 11.

The vapor nozzle 21 has an inlet end with an inner diameter of 1-2 mm and a throat 211 with an inner diameter of 0.6-1.2 mm. An inner diameter of the throat 232 of the mixing section 23 is 1-1.2 mm. In this way, a higher boost ratio and injection ratio can be achieved, thereby improving the performance efficiency of the overall equipment.

In addition, in order to adapt the narrow space of electronic components, the size of the two-phase flow steam injector 2 is relatively small, which is difficult to achieve by conventional mechanical processing methods. Therefore, in this embodiment, the two-phase flow steam injector 2 is processed by means of precision electrospark machining or three-dimensional (3D) printing.

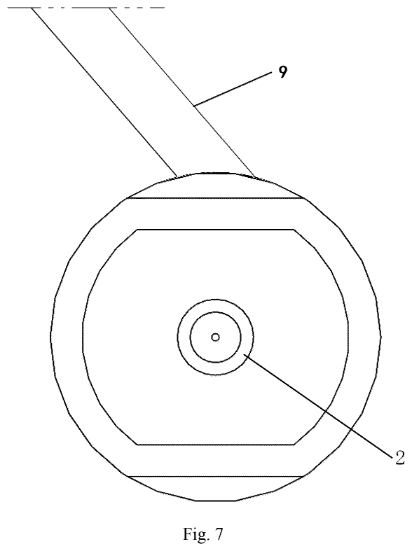

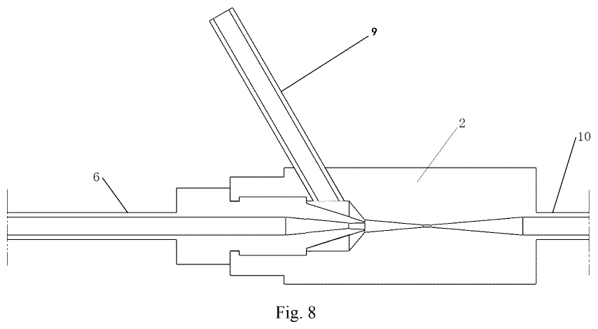

Referring to FIGS. 7 and 8, the second liquid pipeline 9 is inserted into the two-phase flow steam injector 2 at a circumferential angle of 30°-60° and an axial angle of 30°-60°. FIG. 7 shows that the second liquid pipeline 9 is circumferentially inclined by 30°-60° relative to the two-phase flow steam injector 2. FIG. 8 shows that the second liquid pipeline 9 is axially inclined at an angle of 30°-60° relative to the two-phase flow steam injector 2, and is tilted toward the first vapor pipeline 6. That is, the second liquid pipeline 9 is arranged at a circumferential inclination angle of 30°-60° and an axial inclination angle of 30°-60° toward a liquid inlet direction, thereby effectively reducing the flow impact when the liquid enters.

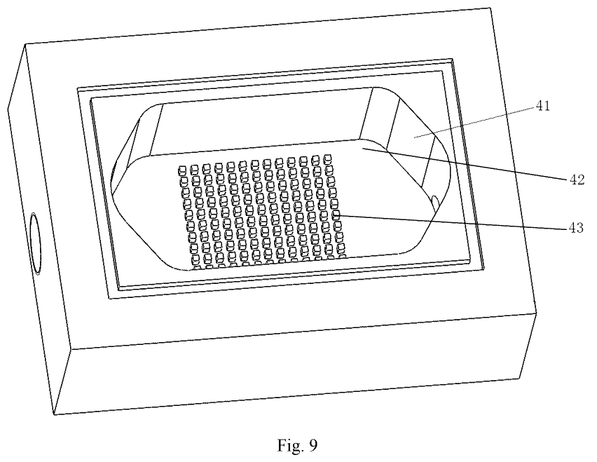

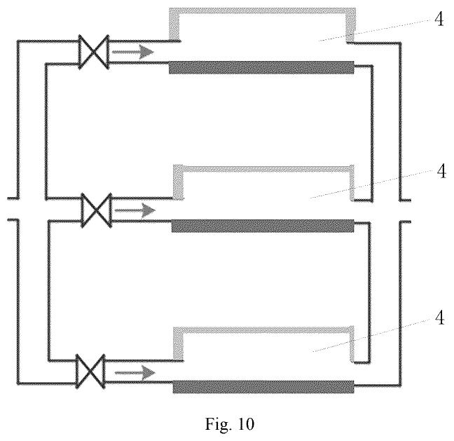

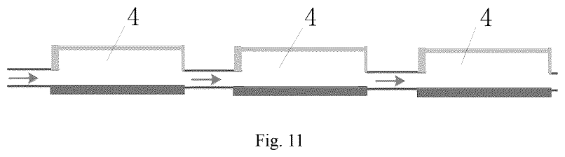

Referring to FIG. 9, the pool boiling of the at least one boiling pool 4 occurs in a small square column or cylindrical cavity, i.e., a cavity 41 of the at least one boiling pool 4. The at least one boiling pool 4 is formed by means of diffusion welding. A bottom surface 42 of each of the at least one boiling pool 4 is provided with a plurality of square column microstructures 43. A gap is provided between any adjacent two of the plurality of square column microstructures 43. A surface of each of the plurality of square column microstructures 43 is sintered with a layer of capillary structure, i.e., micron-sized particles. A microporous structure is formed between the micron-sized particles. The cavity 41 of the at least one boiling pool 4 is shaped in a pattern of gradual expansion followed by a straight section and then gradual contraction, which can effectively reduce the flow resistance. Referring to FIGS. 10 and 11, in order to adapt to the conditions of multiple chip heat sources, in this embodiment, the at least one boiling pool 4 can also be configured as a plurality of boiling pools 4 that are connected in series or in parallel.

A working principle of the embodiment of the present disclosure will be described below.

The wall surface of the at least one evaporator 1 is closely combined with a secondary heating surface of the electronic component, so that heat is conducted to the capillary wick 104 through the metal outer wall of the at least one evaporator 1. The liquid is vaporized after being heated on the surface of the capillary wick 104, and a meniscus is formed at the gas-liquid interface to generate capillary force. The vapor generated thereby enters the first vapor pipeline 6 through the vapor channel 103 and the vapor collecting groove 102. The speed of the vapor at the nozzle rapidly increases to supersonic speed, and a low-pressure zone is formed at the outlet of the vapor nozzle 21, such that the supercooled working fluid after being condensed in the second condenser 5 is effectively ejected and smoothly introduced into the mixing section 23. In the mixing section 23, the supersonic vapor flow directly contacts the supercooled liquid for condensation, and then gradually achieves uniform mixing. In this process, a condensation shock wave is formed at the throat 232 or slightly behind, and the energy is released when the vapor condenses. After passing through the diffusion zone 233, the kinetic energy of the single-phase water is partially converted into potential energy, the flow rate decreases, and the pressure further increases. Finally, a high-pressure single-phase fluid is formed, and flows into the first condenser 3 through the third liquid pipeline 10 for treatment.

The bottom surface of the at least one boiling pool 4 is closely attached to a main heating surface of the electronic component, and heat is effectively transferred to the liquid working fluid in the at least one boiling pool 4 through the bottom surface 42 and the square column microstructure 43. In this process, the liquid evaporates due to heating, thereby forming nucleate boiling. The generated vapor flows to the second condenser 5 through the second vapor pipeline 8, where heat is released. In the second condenser 5, the cooled liquid is then introduced into the liquid nozzle 22 through the second liquid pipeline 9 to complete the liquid recycling process. In this embodiment, during the operation process, the system mainly relies on two driving force sources. The first is the capillary force generated by the capillary wick 104, and the second is the boosting performance provided by the two-phase flow steam injector 2. These two jointly provide power support for the system. As an auxiliary facility, the at least one evaporator 1 generates vapor at a lower power to drive the normal operation of the two-phase flow steam injector 2, and extracts the liquid phase working fluid in the compensation chamber to ensure continuous supply of the liquid phase working fluid in the at least one boiling pool 4. This mechanism effectively promotes the occurrence of flow boiling, thereby achieving efficient heat dissipation of electronic devices.

In the prior art, the gas-liquid flow jet booster mainly adopts water as the working fluid. In order to reduce the operating temperature of the heat pipe, the working fluid of the present disclosure is a low-boiling-point working fluid, such as hydrofluoroolefin refrigerant, and fluorine-containing refrigerant (such as 1,1,1,2-tetrafluoroethane (R-134a), trans-1-chloro-3,3,3-trifluoropropene (R-1233zd (E)), etc.).

The embodiments described above are merely illustrative of the present disclosure, and are not intended to limit the scope of the present disclosure. It should be understood that various changes or substitutions made by those of ordinary skill in the art without departing from the spirit of the present disclosure shall fall within the scope of the present disclosure defined by the appended claims.

What is claimed is:

1. A mechanical pump-free flow boiling heat sink, comprising:
at least one evaporator;
a two-phase flow steam injector;
a first condenser;
at least one boiling pool; and
a second condenser;
wherein a vapor outlet of each of the at least one evaporator is communicated with a vapor-phase inlet of the two-phase flow steam injector;
a liquid-phase outlet of each of the at least one evaporator is communicated with an inlet of a corresponding one of the at least one boiling pool; and
an outlet of each of the at least one boiling pool is communicated with an inlet of the second condenser, and an outlet of the second condenser is communicated with a liquid-phase inlet of the two-phase flow steam injector; and an outlet of the two-phase flow steam injector is communicated with an inlet of the first condenser, and an outlet of the first condenser is communicated with an inlet of each of the at least one evaporator.

2. The mechanical pump-free flow boiling heat sink of claim 1, wherein the two-phase flow steam injector comprises a vapor nozzle, a liquid nozzle and a mixing section; the vapor nozzle and the liquid nozzle are both communicated with the mixing section; the liquid nozzle is located at a periphery of the vapor nozzle; the vapor nozzle is communicated with the vapor outlet of each of the at least one evaporator; and the liquid nozzle is communicated with the outlet of the second condenser.

3. The mechanical pump-free flow boiling heat sink of claim 2, wherein the vapor nozzle and the mixing section are each a Laval nozzle.

4. The mechanical pump-free flow boiling heat sink of claim 3, wherein the mixing section comprises a mixing chamber, a throat and a diffusion zone communicated in sequence; the diffusion zone is communicated with the inlet of the first condenser; the vapor nozzle has an inlet end with an inner diameter of 1-2 mm and a throat with an inner diameter of 0.6-1.2 mm; and an inner diameter of the throat of the mixing section is 1-1.2 mm.

5. The mechanical pump-free flow boiling heat sink of claim 4, wherein the liquid nozzle is connected to the second condenser through a liquid pipeline; and the liquid pipeline is inserted into the two-phase flow steam injector at a circumferential angle of 30°-60° and an axial angle of 30°-60°.

6. The mechanical pump-free flow boiling heat sink of claim 5, wherein each of the at least one evaporator comprises a base plate and a compensation chamber arranged on the base plate; a capillary wick is provided below the compensation chamber; a vapor channel is provided below the capillary wick; a vapor collecting groove is provided at a side of the vapor channel, and is communicated with the vapor channel; and the vapor collecting groove is connected to the vapor nozzle through a vapor pipeline.

7. The mechanical pump-free flow boiling heat sink of claim 6, wherein the capillary wick comprises an upper layer and a lower layer; the lower layer is formed by sintering a brass powder with a particle size of 800-1200 mesh; and the upper layer is formed by sintering a nickel powder with a particle size of 300-500 mesh.

8. The mechanical pump-free flow boiling heat sink of claim 7, wherein the capillary wick and the base plate are molded by integrated sintering.

9. The mechanical pump-free flow boiling heat sink of claim 8, wherein a bottom surface of each of the at least one boiling pool is provided with a plurality of square column microstructures; a gap is provided between any adjacent two of the plurality of square column microstructures; a surface of each of the plurality of square column microstructures is distributed with micron-sized particles by sintering; and a microporous structure is formed between the micron-sized particles.

10. The mechanical pump-free flow boiling heat sink of claim 9, wherein a plurality of evaporators and a plurality of boiling pools are provided; and
the plurality of evaporators are connected in series, and the plurality of boiling pools are connected in series; or
the plurality of evaporators are connected in parallel, and the plurality of boiling pools are connected in parallel.
